(19) United States
(12) Patent Application Publication
(10) Pub. No.: US 2024/0150524 A1
(43) Pub. Date: May 9, 2024

(54) POLYIMIDES HAVING LOW DIELECTRIC LOSS

(71) Applicant: SOLVAY SPECIALTY POLYMERS ITALY S.P.A., Bollate (Milano) (IT)

(72) Inventors: Dipankar Basak, Vadodara (IN); Mattia Bassi, Milano (IT); Rahul Shingte, Vadodara (IN)

(73) Assignee: SOLVAY SPECIALTY POLYMERS ITALY S.P.A., Bollate (Milano) (IT)

(21) Appl. No.: 18/546,726

(22) PCT Filed: Feb. 11, 2022
(86) PCT No.: PCT/EP2022/053320

§ 371 Date: Aug. 16, 2023

(30) Foreign Application Priority Data
Feb. 16, 2021 (IN) 202121006450
Mar. 25, 2021 (EP) 21165039.5
Sep. 16, 2021 (IN) 202121041898

(51) Int. Cl. C08G 73/10; C08K 5/28; C08K 5/5397

(52) U.S. Cl. CPC C08G 73/1025; C08G 73/1039; C08G 73/1071; C08K 5/28; C08K 5/5397

(57) ABSTRACT

The present invention relates to novel polyimide polymers containing certain fluorinated diamine moieties, said polyimide polymers being characterized by excellent dielectric performances. The present invention also relates to the use of said polyimide-based polymers in polymer compositions in microelectronics applications.

This application claims priority from Indian patent application Nr 202121006450 filed on 16 Feb. 2021, European patent application Nr 21165039.5 filed on 25 Mar. 2021, and Indian patent application Nr 202121041898 filed on 16 Sep. 2021, the whole content of each of these applications being incorporated herein by reference for all purposes.

### TECHNICAL FIELD

The present invention relates to polyimide polymers containing certain fluorinated diamine moieties, said polyimide polymers being characterized by excellent dielectric performances, in particular low dielectric loss (Df). The present invention also relates to the use of said polyimide polymers in microelectronics applications.

### BACKGROUND ART

Polyimides are widely used in microelectronics due to their excellent heat resistance, mechanical properties and excellent solvent resistance and radiation resistance. However, their dielectric properties are relatively high: dielectric constant is about 3.4, and dielectric loss factor is 0.005˜0.010). To a certain extent, those values limit their application in different fields.

Therefore, the development of polyimide materials with excellent heat resistance, low dielectric constant and low dielectric loss is of great significance.

Several approaches can be found in the literature to reduce the dielectric constant of polyimide materials. Among those, introducing fluorine and free volumes in the material are methods known in the art to enhance dielectric properties. In particular, fluorine is widely utilized for reducing dielectric constant of materials because it can reduce the strength of dipoles.

For instance, CN10669336 discloses fluorine-containing polyimide resin composition formed by polymerization of fluorine-containing dianhydride (4,4′-(hexafluoroisopropylidene)diphthalic anhydride, hereinafter “6-FDA”) and fluorine-containing diamine (2,2-bis(4-aminophenyl) hexafluoropropane, hereinafter “BPAFDA”), as a matrix, and uses low molecular weight polyphenyl ether with a low dielectric constant and polytetrafluoroethylene as filling modifier.

Other methods for reducing the dielectric properties of polyimides are through pyrolysis, photolysis, solvent method or introduction of microporous materials, to increase the air content, thereby reducing the dielectric constant.

CN109535713 discloses composite materials comprising glass hollow microspheres coated with a polyimide material formed by reaction of 6-FDA and 2,2′-bis(trifluoromethyl)-4,4′-diaminobiphenyl (“TFMB”, hereinafter).

Being insoluble in most common solvents, polyimides are usually processed in the form of their precursor poly(amic acids), which are then thermally converted to the imide structure by thermal imidization.

Polyimides are widely used in the semiconductor industry for passivation films, stress buffer films, particle shielding films, dry etching masks, micro-electromechanical systems, interlayer insulating films and the like. Polyimide materials are often used as a protective coating for integrated circuit devices since polyimide can pass the reliability test for integrated circuit devices. In addition, polyimide plays a key role in electronic packaging, enameled wires, printed circuit boards, sensing elements, separation membranes and structural materials.

It would be advantageous to have polyimide polymers having improved dielectric performances while possessing appropriate solubility and low water absorption.

It has now been found that polyimide polymers comprising recurring units deriving from certain fluorinated diamines have dielectric properties, mechanical properties and water uptake characteristics that can be conveniently modulated to suit the needs of the microelectronic industry.

### SUMMARY OF INVENTION

An object of the present invention is a photosensitive polymer composition comprising:
(a) at least one polyimide-based polymer obtained by polymerizing:
   an aromatic carboxylic acid component [component (AC)];
   a diamine component [diamine (D)], wherein the diamine component is an organic fluorinated diamine of formula (I)

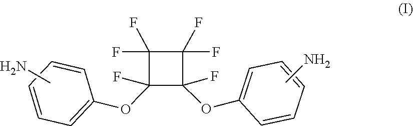

and
optionally, a diamine component [diamine (D1)] different from diamine (D); and
(b) at least one photosensitive agent.

Component (AC) preferably comprises an aromatic tetracarboxylic anhydride.

The polyimide-based polymer may be at least one compound selected from the group consisting of polyimide polymer [polymer (PI)] or a polyamic acid polyimide precursor [polymer (PAA)].

The photosensitive polymer composition of the present invention is useful as material for the production of printed circuit boards, flexible printed circuit boards, as well as copper clad laminates and the like.

Since the polyimide-based polymer dissolves very well in various solvents, it can be suitably used in photo-patterning procedures involving positive or negative development.

The photosensitive polymer composition of the present invention is useful as material for the production of printed circuit boards by a method comprising the steps of exposing a layer of the composition selectively to actinic radiation through a photomask having a pattern and developing the exposed or unexposed part of the layer.

Another object of the present invention is thus a method for forming a pattern in a layer applied on a substrate, said method comprising:
a) applying a coating of the photosensitive polymer composition on a substrate;
b) masking the applied coating with a photomask having a pattern;
c) exposing the masked substrate to a source of actinic radiation and developing the photosensitive film; and
d) heat curing the developed substrate to form a polyimide pattern.

Some of the polyimide-based polymers used in the photosensitive polymer composition as above defined are novel and represent further aspects of the present invention.

In another object, thus, the present invention provides a polyamic acid polyimide precursor [polymer (PAA)] obtained by polymerizing:
an aromatic carboxylic acid component [component (AC)] which is an aromatic tetracarboxylic acid compound selected from those of formula (V):

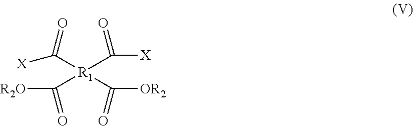

wherein R₁ is an aromatic tetravalent group, which may comprise one or more than one aromatic ring, which may be optionally fused together, R₂ is a C₁-C₂₀ alkyl radical, optionally comprising at least one polymerizable group, and X is OH, Cl, Br, I, preferably OH or Cl, and
a diamine component [diamine (D)], wherein the diamine component is an organic fluorinated diamine of formula (I)

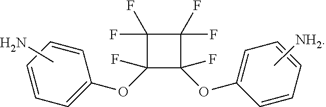

### DESCRIPTION OF EMBODIMENTS

In the context of the present invention, the use of parentheses “( . . . )” before and after symbols or numbers identifying formulae or parts of formulae has the mere purpose of better distinguishing that symbol or number with respect to the rest of the text; thus, said parentheses could also be omitted.

The term “film”, as used herein, is intended to mean a free-standing film or self-supporting or non-self-supporting coating.

As said, the photosensitive polymer compositions of the present invention comprise a polyimide-based polymer that may be at least one compound selected from the group consisting of polyimide polymer [polymer (PI)] or a polyamic acid polyimide precursor [polymer (PAA)], obtained by polymerizing an anhydride component with certain organic fluorinated diamine components.

The term “polyamic acid polyimide precursor” as used herein is intended to include any polyimide precursor material derived from a combination of certain dianhydride and diamine and capable of conversion to polyimide.

As said, the polyamic acid polyimide precursor [polymer (PAA)] suitable for use in the photosensitive polymer compositions of the present invention is obtained by polymerization of:
an aromatic carboxylic acid component [component (AC)],
a diamine component [diamine (D)] wherein the diamine component is an organic fluorinated diamine of formula (I):

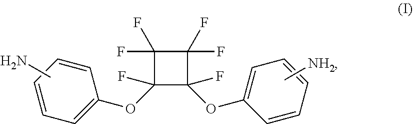

and
optionally, a diamine component [diamine (D1)] different from diamine (D).

Polymer (PAA) comprises amic acid groups. Said amic acid groups may be in acid form or they may be partially or fully in the form of an ester. In certain embodiments the amic acid groups in polymer (PAA) are in the form of an ester of a C₁-C₂₀ alkyl optionally comprising polymerisable groups as detailed hereafter. Accordingly the expression “polymer (PAA)” is used in the remainder of the present specification to include polyamic acid polymers in which part or all of the amic acid groups are in the form of an ester.

Component (AC) may comprise an aromatic tetracarboxylic anhydride. Any aromatic tetracarboxylic anhydride may be used for preparing polymer (PAA).

The aromatic tetracarboxylic anhydride for preparing polymer (PAA) may be selected from the group consisting of pyromellitic dianhydride (PMDA), 3,3′, 4,4′-biphenyl tetracarboxylic dianhydride (BPDA), 4,4′-oxydiphthalic anhydride (ODPA), isomeric diphenyl sulfide dianhydride (TDPA), triphenyl diether dianhydride (HQDPA), 3,3′, 4,4′-benzophenone tetracarboxylic dianhydride (BTDA), 4,4′-bisphenol A dianhydride (BPADA), 3,3′, 4,4′-diphenyl sulfone tetracarboxylic dianhydride (DSDA), 4,4′-(hexafluoroisopropylidene)diphthalic anhydride (6-FDA), 9,9-bis (trifluoromethyl)xanthene tetracarboxylic dianhydride (6FCDA), 1,4-bis(trifluoromethyl)-2,3,5,6 pyromellitic dianhydride (P6FDA), 1,4-bis(3,4-dicarboxy-trifluorophenoxy)tetrafluorobenzene dianhydride (10-FEDA), 2,2-bis[4-(3,4-dicarboxy phenoxy) phenyl] hexafluoropropane dianhydride (BFDA) or 1,4-difluoro pyromellitic dianhydride (PF2DA).

The aromatic tetracarboxylic anhydride may advantageously be selected from the group consisting of pyromellitic dianhydride (PMDA), 4,4′-oxydiphthalic anhydride (ODPA), 4,4′-(hexafluoroisopropylidene)diphthalic anhydride (6-FDA) and 3,3′, 4,4′-biphenyl tetracarboxylic dianhydride (BPDA).

In an embodiment of the invention, component (AC) is a C₁-C₂₀ ester of an aromatic carboxylic acid further comprising carboxylic acid groups which is suitable to form an imide upon reaction with an amine. In a preferred aspect of said embodiment, the carboxylic acid ester group comprises polymerizable side chains.

Polymer (PAA) may be obtained by the polymerization of a component (AC) which is an aromatic tetracarboxylic acid compound selected from those of formula (V):

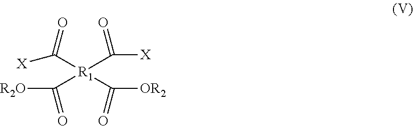

wherein R₁ is an aromatic tetravalent group, which may comprise one or more than one aromatic ring, which may be optionally fused together, R₂ is a C₁-C₂₀ alkyl radical, optionally comprising at least one polymerizable group, and X is OH, Cl, Br, I, preferably OH or Cl.

Component (AC) may consist of an aromatic tetracarboxylic acid compound of formula (V). In such an instance polymer (PAA) will comprise, essentially consist of or consist of amic acid groups in the form of esters. Component (AC) may alternatively comprise an aromatic tetracarboxylic anhydride and an aromatic tetracarboxylic acid compound selected from those of formula (V). In such a case a part of the amic acid groups in polymer (PAA) will be in the form of an ester.

In formula (V), R₁ may be selected from the group consisting of:

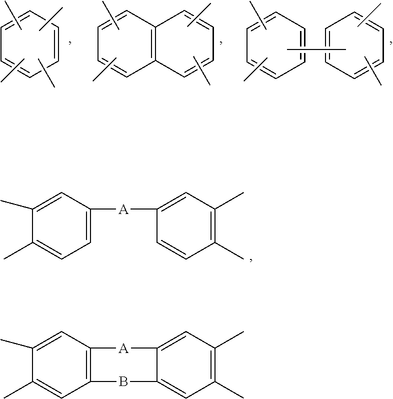

with A being selected from the group consisting of —O—, —C(O)—, —S—, —SO₂—, —SO—, —(CH₂)ₗ— with l an integer from 1 to 6, —C(CH₃)₂—, —C(CF₃)₂—, —(CF₂)ₘ— with m an integer from 1 to 6, cycloalkylenes having 4 to 8 carbon atoms; alkylidenes having 1 to 6 carbon atoms; cycloalkylidenes having 4 to 8 carbon atoms; and B, the same or different from A, being selected from the group consisting of —O—, —C(O)—, —S—, —SO₂—, —SO—, —(CH₂)ₗ— with l an integer from 1 to 6, —C(CH₃)₂—, —C(CF₃)₂—, —(CF₂)ₘ— with m an integer from 1 to 6.

In formula (V), R₂ is a C₁-C₂₀ alkyl radical. In an embodiment of the invention R₂ is a C₁-C₈, preferably a C₁-C₄ alkyl radical, e.g. methyl, ethyl, propyl, butyl radical. In an alternative embodiment of the invention R₂ is selected from C₄-C₂₀ alkyl radicals comprising at least one polymerizable group. The polymerizable group may be selected from:

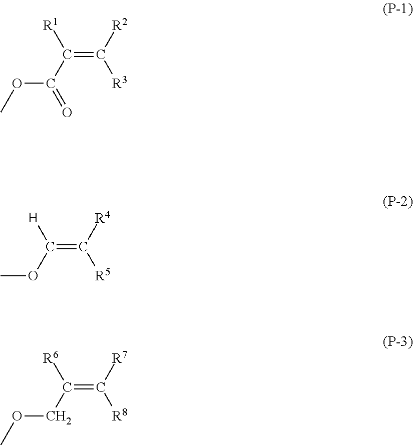

wherein, in formulas (P-1) to (P-3), R1, R2, R3, R4, R5, R6, R7 and R8 are independently hydrogen, methyl, or ethyl; in formula (P-2), at least one of R4 and R5 is methyl or ethyl. Preferably R₂ is selected from C₄-C₂₀ alkyl radicals comprising at least on polymerizable group of formula (P-1). Advantageously, R₂ may be —(CH₂)ₚ—O—C(O)C(R*)═CH₂, where R* is H or a C₁-C₅ alkyl, and p is an integer from 1 to 5; preferably R₂ is —(CH₂)ₚ—O—C(O)C(CH₃)═CH₂, with p equal to 1 or 2.

A non-limiting example of a compound of formula (V) suitable for use in the preparation of polymer (PAA) is:

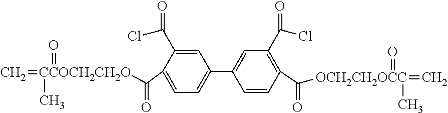

hereinafter referred to as HEMA2-BPDA. HEMA2-BPDA can be prepared according to the method disclosed in U.S. Pat. No. 4,040,831.

One or more than one aromatic tetracarboxylic anhydride and/or compound of formula (V) can be used in the preparation of polymer (PAA) in combination with diamine (D) and optionally diamine (D1).

Diamine (D) is an organic fluorinated diamine of formula (I).

The amount of diamine (D) in polymer (PAA) may range from 100.0 mol % to 0.1 mol % with respect to the total amount of moles of diamine units in the polymer.

In a first embodiment diamine (D) is the sole diamine in polyamic acid polymer (PAA), that is diamine (D) represents 100.0 mol % of the total amount of moles of diamine units in the polymer.

In such an embodiment polymer (PAA) typically consists of recurring units deriving from diamine (D) and at least one aromatic tetracarboxylic anhydride as above detailed.

Polymer (PAA) may optionally comprise a further diamine (D1) different from the diamine (D) of formula (I). In such an embodiment, polymer (PAA) comprises diamine (D) and at least one diamine (D1). The amount of diamine (D) may range from 99.9 to 0.1 mol % of the total amount of moles of diamine units in the polymer.

Advantageously, the amount of diamine (D) may be 95.0 to 5.0 mol %, 90.0 to 10.0 mol %, 75.0 to 10.0 mol %, 75.0 to 12.0 mol % of the total amount of moles of diamine units in the polymer (PAA).

Suitable diamines (D1) that can be used in preparing polymer (PAA) are selected from the group consisting of 4,4′-diaminodiphenyl ether (ODA), p-phenylenediamine, (PDA), 3,3′-Diamino-5, 5′-bis (trifluoromethyl) biphenyl (TFMB), m-phenylenediamine, diphenyl dimethyl methane diamine (DMMDA), 1,3-bis (3-aminophenoxy) benzene (BAPB), 4,4′-bisphenol A ether diamine (BAPP), 4,4′-bis (4-aminophenoxy) diphenylsulfone (BAPS), 4,4′-bis (4-aminophenoxy) diphenyl ether (BAPE), diamino diphenyl (methyl) ketone (DABP), 4,4′-diamino-triphenylamine (DATPA), 4,4′-diaminodiphenyl methane (MDA), diaminodiphenyl sulfone (DDS), 3,4′-diaminodiphenyl ether (3,4′-ODA), 3,3′-dimethyl-4,4′-diamino diphenyl methane (MDI), 4,4′-diamino-diphenoxy-1″,4″-benzene, 4,4′-diamino-diphenoxy-1″,3″-benzene, 3,3′-diamino-diphenoxy-1″,3″-benzene, 4,4′-diamino-diphenyl-4″,4-phenyl-isopropyl propane, perfluorinated isopropylidene diamine (4-BDAF), 2,2-bis (4-aminophenyl) hexafluoropropane (6FDAM), 1,4-bis-(4-amino-2-trifluoromethylphenoxy) benzene (6FAPB), 2,5-bis(4-amino-2-trifluoromethyl-phenoxy)-tert benzene (DNTBHQ-2TF), 4,4′-bis (4-amino-2-trifluoromethyl-phenoxy)-biphenyl (DNBP-2TF), 5-trifluoromethyl-1,3-diaminobenzene (TFMB), 5-trifluoromethoxy-1,3-diaminobenzene (TFMOB), 1,4-diamino-2,3,5,6-tetrafluoro-benzene (4FPPD), 4,4′-diamino octafluoro biphenyl (8FZB), 4,4′-diamino diphenyl ether octafluoro (8FODB), bis (3-amino-phenyl)-4-(trifluoromethyl) phenyl phosphine oxide (m-DA6FPPO), or 2,2-bis(4-aminophenyl)hexafluoropropane (BPAFDA).

Advantageously polymer (PAA) may be obtained by polymerizing:
a) a component (AC),
b) 5.0 to 95.0 mol %, 15.0 to 85.0 mol %, even 20.0 to 80.0 mol % of diamine (D), and
c) 5.0 to 95.0 mol %, 15.0 to 85.0 mol %, even 20.0 to 80.0 mol % of diamine (D1).

The molar percentages of diamine (D) and diamine (D1) are expressed with respect to the total amount of moles of diamine units (diamine (D)+diamine (D1)) in the polymer.

Polymer (PAA) of the present invention can be obtained by any known method, and is not limited to a particular production method.

The polymerization of the anhydride component with diamine (D) and optionally diamine (D1) is suitably carried out at a temperature of −20 to 150° C., preferably −5 to 100° C. Polymerization is typically carried out in a polar solvent. Suitable solvents are N,N-dimethylformamide, N,N-dimethylacetamide, N-methylpyrrolidone, N-vinylpyrrolidone, N-methylcaprolactam, dimethylsulfoxide, tetramethylurea, pyridine, dimethylsulfone, hexamethylsulfoxide, m-cresol, γ-butyrolactone and mixtures thereof. The result is a polyamic acid polymer, precursor to a polyimide polymer, in the form of a solution in said solvent.

In this specification, a solution containing a polyamic acid and an organic solvent is meant to be a “polyamic acid solution”. In a case where the polyamic acid is obtained by the above described method, a reaction solution as obtained at the end of the polymerization process is sometimes referred to as “polyamic acid solution”.

In performing the polymerization reaction of the polyamic acid, a solution viscosity may be properly chosen depending upon a purpose of the use (coating, casting, etc.) or a purpose of the production. From the viewpoint of workability, it is desirable that the polyamic acid solution (polyimide precursor solution) has a rotational viscosity, as measured at 30° C., of from about 0.01 to 900 Pa·s, preferably from 0.01 to 400 Pa·s, and more preferably from 0.02 to 400 Pa·s. In consequence, it is preferable that the polymerization reaction is carried out to an extent that the formed polyamic acid exhibits the foregoing viscosity.

The polyamic acid polymer (PAA) can be isolated in the form of powder by precipitating the same with water from the polyamic acid solution as above defined and drying.

The polyamic acid polymer solution as above defined can also be used as such in the preparation of an article or it can be converted into a polyimide polymer [polymer (PI)].

Accordingly, in a further object, the present invention provides a polyimide polymer (PI) obtainable from polymer (PAA).

Polymer (PI) of the present invention can be obtained by dehydrating and ring closing the polymer (PAA) by any known method, and is not limited to a particular production method.

According to one embodiment of the present invention, polyamic acid polymer (PAA) is imidized in order to obtain a polyimide polymer (PI) by cyclodehydration of the polyamic acid. The cyclodehydration can be carried out with an azeotropic method using an azeotropic solvent, with a thermal method, or with a chemical method. The imidization from polyamic acid to polyimide can be carried out with any ratio between 1% and 100%. That is, it is possible to synthesize a polyamic acid which is partially imidized.

The cyclodehydration can be carried out by a thermal method, thus by heating polymer (PAA). The method for heating polymer (PAA) is not limited to a particular one, and can be, for example, a method in which the polyamic acid solution is cast or applied to a support such as a glass plate, a metal plate, or PET (polyethylene terephthalate), and then it is heat treated at a temperature in a range between 80° C. and 500° C. A film of polyimide polymer (PI) can thus be obtained by this method.

Alternatively, the cyclodehydration of polymer (PAA) can be carried out by an azeotropic method, including adding an azeotropic solvent and drying the polyamic acid solution with heat under reduced pressure. In general, it is preferable that heating is carried out for a time in a range between 1 minute and 5 hours.

Alternatively, in order to reduce heating time and to obtain a polyimide having certain improved characteristics, a polyamic acid solution can be imidized by a chemical method including the addition of an imidizing agent and/or a dehydrating catalyst followed by heating with the azeotropic method as above described.

The imidizing agent is not limited to a particular one and can be tertiary amine. The tertiary amine is further preferably a heterocyclic tertiary amine. Suitable examples of the heterocyclic tertiary amine preferably encompass pyridine, picoline, quinoline, and isoquinoline. Suitable examples of the dehydrating catalyst preferably encompass acetic anhydride, propionic anhydride, n-butyric anhydride, benzoic anhydride, and trifluoroacetic anhydride.

When adding the imidizing agent and/or the dehydrating catalyst to the polyamic acid solution, the imidizing agent and/or the dehydrating catalyst can be added directly without being dissolved in an organic solvent or can be dissolved in an organic solvent and then added.

Polymer (PI) obtained by imidization of polymer (PAA) according to any of the methods as above defined is characterized by improved dielectric properties, in particular in terms of low dielectric constant and low dielectric loss.

The dielectric constant (Dk) of polymer (PI) is typically less than 4.0, even less than 3.5 and still less than 3.0 at 20 GHz.

The dielectric loss (Df) of the polyimide polymer [polymer (PI)] suitable for use in the photosensitive polymer compositions of the present invention is <0.005 at 20 GHz.

Water uptake of the polymer (PI) suitable for use in the photosensitive polymer compositions of the present invention is <1% after immersion in water at room temperature for 24 h.

Polymer (PI), thanks to the peculiar monomer composition, is also characterized by being soluble in various organic solvents, in particular in organic polar solvents used in microelectronics industry such as N-methylpyrrolidone (NMP), γ-butyrolactone (GBL), propylene glycol monomethyl ether acetate (PGMEA) or cyclopentanone (CP).

As used herein “soluble” means that at least 99 wt % of polymer (PI) dissolves in said solvents to form a homogenous solution.

Since the inventive polyimide-based polymer has excellent solubility in various polar organic solvents, the inventive photosensitive composition can be suitably used in patterning procedures involving positive- or negative-type pattern forming.

The photosensitive polymer composition of the present invention is suitably prepared by dissolving the polyimide-based polymer and the photo sensitive agent as above defined into a polar organic solvent. The solvent may be any of those capable of dissolving the polyimide polymer. For example, the solvent is selected from the group consisting of N,N-dimethylformamide, N,N-dimethylacetamide, N-methylpyrrolidone, N-vinylpyrrolidone, N-methylcaprolactam, dimethylsulfoxide, tetramethylurea, pyridine, dimethylsulfone, hexamethylsulfoxide, m-cresol, γ-butyrolactone, ethyl cellosolve, butyl cellosolve, ethyl carbitol, butyl carbitol, ethyl carbitol acetate, butyl carbitol acetate, ethylene glycol, ethyl lactate, butyl lactate, cyclohexanone, cyclopentanone, and mixtures thereof. Preferably, the solvent is selected from the group consisting of N-methylpyrrolidone and γ-butyrolactone.

The solvent is preferably present in an amount of 30 to 90 parts by weight, based on 100 parts by weight of the polyimide polymer.

The photosensitive agent is preferably present in the photosensitive polymer composition in an amount of 1 to 50 parts by weight, based on 100 parts by weight of the polyimide-based polymer.

The photosensitive polymer composition of the present invention may further comprise one or more additives selected from dissolution rate modifiers, sensitizers, adhesion promoters and surfactants. 0.1 to 20 parts by weight of each of the additives can be used for every 100 parts by weight of the polyimide-based polymer. Suitable sensitizers may be selected from perylene, anthracene, thioxanthone, Michler's ketone, benzophenone and fluorene. Suitable adhesion promoters may be selected from 3-(trimethoxysilyl)propyl methacrylate, N-[3-(trimethoxy-si)propyl]aniline, trimethoxy(3,3,3-trifluoropropyl)silane.

In a preferred embodiment, the photosensitive polymer composition of the present invention comprises:
from 1 to 70 parts by weight of polyimide-based polymer;
from 1 to 30 parts by weight of a photosensitive agent,
from 0 to 20 parts by weight of one or more additives as above defined, with respect to a total of 100 parts by weight of the photosensitive polymer composition.

According to the present invention, any photosensitive agent can be used which decreases or increases the solubility of polyimide-based polymer after exposure to actinic radiation. In such a way the solubility of the polymer which has been exposed to actinic radiation is differentiated from that of the non-exposed polymer and an appropriate pattern can be obtained.

The photosensitive polymer composition of the present invention can be used in a pattern forming method, said method comprising:
a) applying a coating of the photosensitive polymer composition on a substrate;
b) masking the applied coating with a photomask having a pattern;
c) exposing the masked substrate to a source of actinic radiation and developing the substrate; and
d) heat curing the developed substrate to form a polyimide pattern.

In step a) of the process, the polymer composition comprising the polyimide-based polymer, the photosensitive agent and a polar organic solvent is applied to a substrate, typically by coating. The substrate may be glass or a silicon wafer. Any known coating process may be used, such as spin coating, slit spin coating, roll coating, die coating or curtain coating. Coating of the composition comprising the polyimide-based polymer leads to the formation of a film on the surface of the substrate, which is followed by thermosetting the applied composition by pre-baking the resulting film at a temperature comprised between 50 and 120° C., to allow the solvent to be volatilized.

The thickness of the film obtained in step a) may vary depending on the intended purpose. The thickness of the film is preferably in the range of from 0.1 to 100 microns, preferably from 1 to 50 micron, more preferably from 5 to 20 microns, even more preferably the thickness is of 10 to 15 microns.

In step b) of the process, the coating of photosensitive polymer composition provided in step a) is masked by a photomask having a predetermined pattern and it is exposed, along with the photomask to actinic radiation. Exposure is performed with radiation at a suitable wavelength and for a sufficient time to promote the desired change in the solubility of the polyimide-based polymer which is required.

Actinic radiation used for the exposure process is not particularly limited. For example, electromagnetic radiation, visible light, UV light, electron beam, X ray or a laser can be used to irradiate the photosensitive film.

Thereafter, the exposed photosensitive film is developed with a developer to remove the exposed or non-exposed region, leaving the desired pattern.

The developer is not particularly limited and it depends on whether a positive-type or a negative-type pattern formation is performed.

After development, the developed substrate is converted into a heat-resistant polyimide film by means of a further heat treatment step, typically referred to as “post-bake treatment”. Post-baking is usually performed at 150° C. to 300° C. for 1 to 120 minutes on a hot plate, or for 10 to 120 minutes at the same temperature range in an oven. A completely hardened polyimide film is obtained after post-baking.

In the case of positive-type pattern forming, solubility of the exposed film is generally improved so that upon treatment with appropriate developer solutions the region of the substrate exposed to actinic radiation is removed.

In a first embodiment of the invention photosensitive compositions suitable for use in positive-type pattern forming methods are provided.

Suitable compounds used as the photosensitive agent for said positive-type pattern forming method include, for example, o-quinone diazide compounds, azide compounds and diazo compounds. O-quinone diazide compounds are preferred in terms of sensitivity or resolution.

The o-quinone diazide compound can be selected from a great number of compounds of various structures having at least one o-quinone diazide group, in which the solubility is modified upon irradiation.

In particular, various o-quinone diazide sulfonic acid esters or sulfone amides are preferred. The following o-quinone diazide sulfonic acid esters can suitably be used as photo sensitive agent in the present invention:

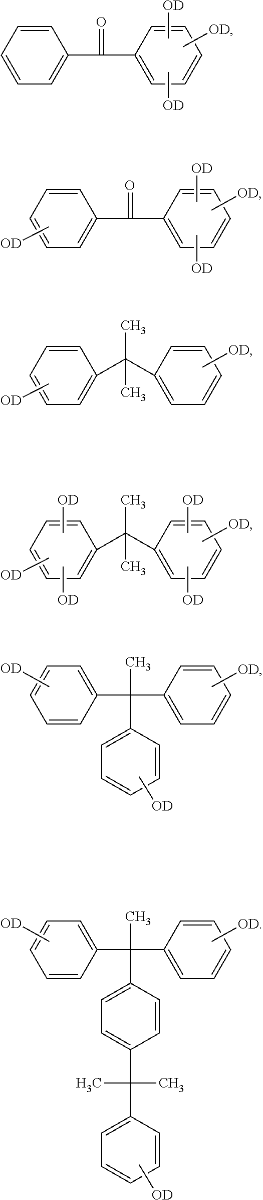

wherein in each of the formulas above, D is selected from the following compounds:

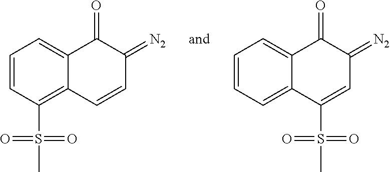

Typical examples of o-quinone diazide sulfonic acid esters are 2,2′-dihydroxy-diphenyl-bis-(naphthoquinone-1,2-diazide-5-sulfonic acid ester), 2,3,4-trihydroxybenzophenone bis-(naphthoquinone-1,2-diazide-5-sulfonic acid ester), 2,7-dihydroxynaphthalene-bis-(naphthoquinone-1,2-diazide-5-sulfonic acid ester) and the ester of a phenol formaldehyde resin and naphthoquinone-1,2-diazide-5-sulfonic acid.

Suitable developers for positive-type pattern forming compositions and methods are water, an organic solvent, an alkaline aqueous solution or a mixture thereof. Suitable alkaline aqueous solutions include aqueous solutions of an alkali metal or alkaline earth metal hydroxide or carbonate, a hydrogen carbonate, ammonia water or a quaternary ammonium salt.

The developer may contain a surfactant, a defoaming agent, an organic base (e.g., benzylamine, ethylenediamine, ethanolamine, tetramethylammonium hydroxide, diethylenetriamine, triethylenepentamine, morpholine or triethanolamine), an organic solvent as a development promoter (e.g., an alcohol, a ketone, an ester, an ether, an amide or a lactone), etc.

In an alternative embodiment of the invention, photosensitive compositions which are particularly suitable for use in a negative-type pattern forming method are provided. In such an embodiment, the polyimide-based polymer is preferably obtained by polymerizing: a component (AC) selected from those of formula (V) wherein R₂ is selected from C₄-C₂₀ alkyl radicals comprising at least one polymerizable group, a diamine (D), and optionally a diamine (D1).

Particularly advantageous are compositions comprising a polyimide-based polymer obtained by polymerizing a component (AC) selected from those of formula (V) wherein R₂ is selected from C₄-C₂₀ alkyl radicals comprising at least on polymerizable group of formula (P-1). Preferably R₂ is —(CH₂)ₚ—O—C(O)C(R*)═CH₂, where R* is H or a C₁-C₅ alkyl group, and p is an integer from 1 to 5. More preferably R₂ is —(CH₂)ₚ—O—C(O)C(CH₃)═CH₂, with p equal to 1 or 2.

The photosensitive agent in said compositions is selected among those compounds which are capable, under actinic radiation, to promote the polymerization of the polymerizable groups which are present in component (AC) of formula (V).

Suitable photosensitive agents may be selected among known radical polymerization initiators. Non-limiting examples are for instance: acylphosphine oxides, such as bis(2,4,6-trimethylbenzoyl)-phenylphosphineoxide, benzophenone and its derivatives, such as 4,4′-bis(dimethylamino)benzophenone, oximes and oxime esters, such as 1-phenyl propanedione-2-(o-methoxycarbonyl)oxime, 1-phenyl-3-ethoxy-propanetrione-2-(o-benzoyl)oxime; acetophenone derivatives, such as 2-hydroxy-2-methylpropiophenone, 2,2′-diethoxyacetophenone.

The photosensitive composition may further comprise cross-linking agents. Non-limiting examples of suitable cross-linking agents are triallylisocyanurate (TAIC), bisphenol A dimethacrylate and its derivatives, 1,6-hexanediol diacrylate, trimethylolpropane triacrylate (TMPTA), trimethylolpropane methacrylate (TMPTMA), dipentaerythritol hexaacrylate, dipentaerythritol methacrylate.

When the photosensitive polymer composition of the present invention is used in a negative-type pattern forming method, in step c) of the method the exposed substrate is developed with a developer to remove the polyimide-based polymer in the non-exposed region of the substrate, leaving the desired pattern.

The developer is not particularly limited. As the developer, there can be exemplified any solvent in which the polyimide-based polymer is soluble, such as cyclopentanone, gamma-butyrolactone, 1-methoxy-2-propanol acetate, Rhodiasolv® Polar clean, N-methyl-2-pyrrolidone (NMP).

In the case of using a polyimide polymer (PI) as the polyimide-based polymer in the photosensitive polymer composition, conversion of polyamic acid precursor into a polyimide is not involved, and thus the relief pattern can be formed at a lower temperature. The pattern-forming method in this case thus requires in step d) a low postbaking temperature, typically the range of from 180 to 200° C.

In the alternative case of using a polyamic acid polymer as polyimide-based polymer in the photosensitive polymer composition, the developed film containing a polyamic acid precursor is subjected in step d) to a thermal process to have the full imidization and postbaking of the film. The developed film containing a polyimide precursor is thus heated at a temperature of at least 300° C., preferably in the range of from 300 to 350° C., to convert the polyamic acid into a polyimide and curing the resulting film to obtain the final polyimide pattern.

In another object, the present invention provides a polyamic ester polyimide precursor obtained by polymerizing:
an aromatic carboxylic acid component selected from those of formula (V):

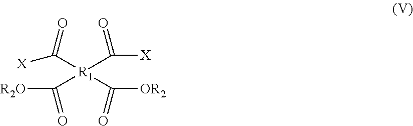

wherein R₁ is an aromatic tetravalent group, which may comprise one or more than one aromatic ring, which may be optionally fused together, R₂ is a C₁-C₂₀ alkyl radical, optionally comprising at least one polymerizable group, and X is OH, Cl, Br, I, preferably OH or Cl;
a diamine component [diamine (D)], wherein the diamine component is an organic fluorinated diamine of formula (I)

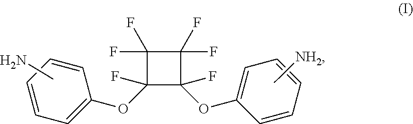

and
optionally, a diamine component [diamine (D1)] different from diamine (D).

According to a preferred embodiment, the polyamic ester polyimide precursor of the present invention is obtained by polymerizing an aromatic carboxylic acid component of formula (V) wherein R₂ is selected from C₄-C₂₀ alkyl radicals comprising at least one polymerizable group. The polymerizable group may be selected from:

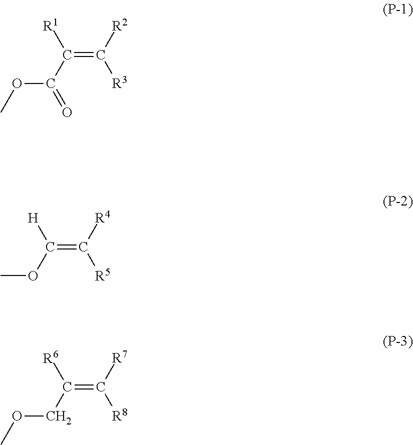

wherein, in formulas (P-1) to (P-3), R1, R2, R3, R4, R5, R6, R7 and R8 are independently hydrogen, methyl, or ethyl; in formula (P-2), at least one of R4 and R5 is methyl or ethyl. Preferably R₂ is selected from C₄-C₂₀ alkyl radicals comprising at least on polymerizable group of formula (P-1). Advantageously, R₂ may be —(CH₂)ₚ—O—C(O)C(R*)═CH₂, where R* is H or a C₁-C₅ alkyl, and p is an integer from 1 to 5; preferably R₂ is —(CH₂)ₚ—O—C(O)C(CH₃)═CH₂, with p equal to 1 or 2.

The polyamic ester precursor of the present invention can be prepared according to any method described above in relation with the preparation of component a) of the photosensitive compositions of the present invention.

The polyamic ester polyimide precursor of the present invention as well as the photosensitive compositions comprising the polyimide-based polymer are suitable for the formation of interlayer insulating films, passivation films, buffer coating films or as insulating films for multilayer printed boards of semiconductor devices. The polymer composition of the present invention is suitable for the formation of redistribution layers in microchips.

Accordingly a further object of the invention are articles comprising the polyimide-based polymer. In particular, articles comprising at least one layer obtained from the photoactive composition of the invention.

All the preferences detailed above in respect of polymer (PAA), polyimide polymer (PI) and the polyamic ester polymer equally apply to the compositions comprising at least one of said polymers as well as to the films or articles obtained therefrom as well as to the methods for making a film or a pattern.

Should the disclosure of any patents, patent applications, and publications which are incorporated herein by reference conflict with the description of the present application to the extent that it may render a term unclear, the present description shall take precedence.

The invention will be now described with reference to the following examples, whose purpose is merely illustrative and not limitative of the present invention.

### EXAMPLES

### Raw Materials

Bis(4-aminophenoxy)hexafluorocyclobutane (DPFCB-N) was prepared according to the method described in WO2020/229227.

3,3′-diamino-5,5′-bis 9(trifluoromethyl) biphenyl (3,3-TFMB) commercially available from TCI Chemicals (India) Pvt. Ltd.

3,3′,4,4′-biphenyl tetracarboxylic dianhydride (BPDA), commercially available from Sigma Adrich.

4,4′-(hexafluoroisopropylidene)diphthalic anhydride (6-FDA), commercially available from Chem-Impex Int'l Inc.

4,4′-oxydiphthalic anhydride (ODPA), commercially available from TCI Chemicals (India) Pvt. Ltd.

p-phenylenediamine (PDA), commercially available from TCI Chemicals (India) Pvt. Ltd.

2,2-Bis(4-aminophenyl)hexafluoropropane (BPAFDA), commercially available from TCI Chemicals (India) Pvt. Ltd.

Photosensitive agent: 2,3,4-trihyoxybenzophenone bis-(naphthoquinone-1,2-diazide-5-sulfonic acid ester, commercially available from Miwon Commercial Co., Ltd.

Tetramethylammoniumhydroxide (TMAH), commercially available from Sigma Aldrich.

For polyimide synthesis, dianhydrides 6-FDA, ODPA, and BPDA were purified by vacuum sublimation before the reaction. The amines 3,3-TFMB, PDA and BPAFDA were freshly distilled/crystallized before use and stored under inert atmosphere in the dark. All the solvents were freshly distilled and dried as per standard drying procedure before the reaction.

### Mechanical Property Measurements

Mechanical properties were measured on a ZWICK Z030 with 1N load cell using ASTM D638 Type V specimen, speed 10 mm/min.

Dynamic mechanical analyzer (DMA) was performed on polyimide films using TA instrument RSA-G2 from 25° C. to 350° C. with temperature ramping rate 3° C./min under nitrogen.

### Thermal Analysis

TGA measurements were performed on a Q500-TA instruments in N₂ atmosphere.

DSC measurements were performed on a Q2000-TA instruments in N₂ atmosphere.

Dielectric measurement: Dielectric constant (Dk) and dielectric loss (Df) were measured at 20 GHz using split cylinder dielectric resonator following IPC-TM-650 2.5.5.13 standard method.

### Viscosity Measurement

Viscosity of polyamic acid solution was measured by Brookfield Viscometer at 30° C. (200 rpm, spindle 34).

Viscosity of polyimide resin was measured by Dilute Solution Viscometer in NMP at 30° C. at 0.75 wt % of solid concentration (SI Analytics, capillary number: 1068421).

### Example 1: Preparation of Polyamic Acid A1

In a typical polymerization, a three-necked round bottom flask, equipped with magnetic stirrer, nitrogen inlet/outlet was charged with bis(4-aminophenoxy)hexafluorocyclobutane (DPFCB-N) (38.7 mmol) and dimethylacetamide (DMAc, hereinafter) (15 wt % solid content). To this stirring solution, 4,4′-(hexafluoroisopropylidene)diphthalic anhydride (6-FDA) (38.7 mmol) was added in portion and the resulting solution was allowed to stir at room temperature for 8 h to obtain a viscous poly(amic acid) solution which was stored in refrigerator for further use. Composition and solubility in some solvents of Al are shown in Table 1.

### Example 2 and Comparative Examples C1-C3

Following the procedure of Example 1, polyamic acid A2 and polyamic acids of comparative examples C1 to C3 were prepared starting from different diamine compounds and different dianhydride compounds. Compositions and solubility in some solvents of the resulting polyamic acids are shown in Table 1.

TABLE 1

| | | | Solubility* | | |
|---|---|---|---|---|---|
| | ANHYDRIDE | AMINE | (15% solid concentration, 25° C.) | | |
| | Molar ratio | | DMAc | NMP | GBL |
| A1 | 6-FDA | DPFCB-N | S | S | S |
| | 1 | 1 | | | |
| A2 | ODPA | DPFCB-N | S | S | S |
| | 1 | 1 | | | |
| C1 | 6-FDA | BPAFDA | S | S | S |
| | 1 | 1 | | | |
| C2 | ODPA | BPAFDA | S | S | S |
| | 1.0 | 1 | | | |
| C3 | 6-FDA | TFMB | S | S | S |
| | 1 | 1 | | | |

*S means soluble, giving a homogeneous solution.

### Example 3: Polyimide Polymer Preparation

Under the flow of dry nitrogen, diamine compound DPFCB-N (8.43 mmol) was dissolved in NMP (30 mL). To this stirring solution, dianhydride compound 6-FDA (8.43 mmol) was added in portion and the solution was stirred at 25° C. for 8 h. Subsequently, toluene (12 mL), GBL (0.145 g, 1.65 mmol) and pyridine (0.26 g, 3.3 mmol) were added and the temperature was raised to 180° C. The solution was stirred at this temperature for 4 h while the water was removed by azeotropic distillation. The solution was cooled down to room temperature and the polyimide resin was precipitated from water and filtered. The polymer powder was washed with hot water, followed by washing with MeOH and dried in vacuum oven at 90° C. for 8 h. Polyimide B1 was thus obtained.

Viscosity and solubility in some solvents is shown in Table 2.

TABLE 2

| | | Solubility * | | | | |
|---|---|---|---|---|---|---|
| | Inherent Viscosity | (25% solid concentration, 25° C.) | | | | |
| | (mL/g) | NMP | DMAc | GBL | PGMA | CP |
| B1 | 0.37 | S | S | S | S | S |

* S means soluble, giving a homogeneous solution.

The data demonstrate that the polyimide polymer B1 is soluble in many different solvents.

For the person skilled in art, inherent viscosity of a polymer can be adjusted based on monomer stoichiometry.

### Example 4: Polyimide Film Preparation for Dielectric Measurement

The viscous polyamic acid solutions as obtained in Example 1 and 2 and Comparative Examples C1-C3 were filtered through PTFE syringe (0.45μ) and cast on a glass substrate by bar-coating. Each cast film was transferred to a flat oven and slowly cured at a temperature from 50° C. to 300° C. and finally at 300° C. for 1.0 h to obtain transparent films (Thickness: 30-40 micron).

Dielectric properties, thermal analyses and mechanical properties of obtained films F1-F2 and comparative films CF1-CF3 are shown in Table 3 and Table 4.

TABLE 3

| | |
|---|---|
| ANHYDRIDE | AMINE |

| | | |
|---|---|---|
| Molar ratio | Dk | Df |

| | | | | |
|---|---|---|---|---|
| F1 | 6-FDA | DPFCB-N | 2.5 | 0.0050 |
| | 1 | 1 | | |
| F2 | ODPA | DPFCB-N | 2.4 | 0.0047 |
| | 1 | 1 | | |
| CF1 | 6-FDA | BPAFDA | 2.8 | 0.0075 |
| | 1 | 1 | | |
| CF2 | ODPA | BPAFDA | 2.7 | 0.0062 |
| | 1 | 1 | | |
| CF3 | 6-FDA | TFMB | 2.5 | 0.0069 |
| | 1 | 1 | | |

TABLE 4′

| | | Isothermal | | | |
|---|---|---|---|---|---|
| | | TGA | | | |
| | TGA | (300° C./1 h), | Tangδ | Strength | Modulus |
| | (5% loss/° C.) | % loss | (DMA) | (MPa) | (GPa) |
| F1 | 490 | 0.4 | 257 | 95 | 3 |
| F2 | 494 | 0.2 | 235 | Brittle | Brittle |
| CF1 | 509 | 0.2 | 317 | 70 | 3.4 |
| CF2 | 526 | 0.6 | 297 | 110 | 3 |
| CF3 | 514 | 0.5 | 340 | 128 | 4 |

The data show that the polyimides used in the present invention are characterized by improved dielectric properties in comparison with polyimides prepared by polymerizing different diamine monomers, while keeping the good mechanical properties usually associated with other polyimides. In particular, the Applicant has surprisingly found that the selection of some specific organic fluorinated diamines as monomers for preparing the polyimides of the present invention allows obtaining polyimides having improved dielectric properties when in comparison with polyimides prepared by reacting other fluorinated diamines.

### Example 5: Photo-Patterning of Polyamic Acid

A 10-μm thick photosensitive film was prepared by dissolving polyamic acid powder obtained as in Example 1 and a photosensitive agent to obtain a composition comprising: polyamic acid 70 wt %, photosensitive agent 30 wt %, GBL: 65 wt %. This photosensitive composition was spin coated on a silicon wafer and the resulting film was pre-baked at 60° C./5 min, and 90° C./5 min. Afterwards, the thin film along with a mask, was exposed to UV light (400-600 mJ/cm²), and developed with 2.38 wt % of aqueous TMAH solution, followed by rinsing with water to obtain positive tone photo-patterning. Subsequently, the wafer was post baked in an oven under the flow of nitrogen where the temperature was raised slowly to ˜300° C. and finally the sample was cured at 300° C. for 1 h to obtain the final pattern.

### Example 6: Photo-Patterning of Polyimide Polymer

A 10-μm thick photosensitive film was prepared by dissolving polyimide resin and photosensitive agent to obtain a composition comprising: polyimide 70 wt %, photosensitive agent 30 wt %, GBL: 65 wt %. This photosensitive composition was spin coated on a silicon wafer and the resulting film was This photosensitive composition was spin coated on a silicon wafer and the resulting film was pre-baked at 60° C./10 min, and 90° C./10 min. Afterwards, the thin film along with a mask, was exposed to UV light (400-600 mJ/cm²), and developed in a solvent mixture of ethanolamine/GBL/water at 25° C. for 2-5 minutes, followed by rinsing with water or water/isopropanol mixture to obtain positive tone photo-patterning. Subsequently, the sample was cured in an oven at 190° C./30 min under the flow of nitrogen to obtain the final pattern.

1. A photosensitive polymer composition, comprising:
(a) at least one polyimide-based polymer obtained by polymerizing:
an aromatic carboxylic acid component, component (AC);
a diamine component, diamine (D), wherein diamine (D) is an organic fluorinated diamine of formula (I): 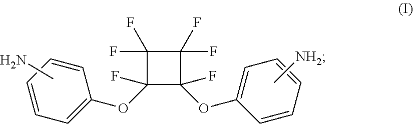
and
optionally, a diamine component, diamine (D1) different from diamine (D).

2. The photosensitive polymer composition according to claim 1 wherein component (AC) is an aromatic tetracarboxylic anhydride.

3. The photosensitive polymer composition according to claim 1 wherein component (AC) is selected from the group consisting of pyromellitic dianhydride (PMDA), 4,4′-oxydiphthalic anhydride (ODPA), 4,4′-(hexafluoroisopropylidene)diphthalic anhydride (6-FDA), and 3,3′,4,4′-biphenyl tetracarboxylic dianhydride (BPDA).

4. The photosensitive polymer composition according to claim 1 wherein component (AC) is selected from the compounds of formula (V): 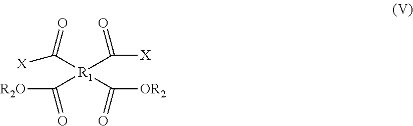
wherein R₁ is an aromatic tetravalent group, which may comprise one or more than one aromatic ring, which may be optionally fused together, R₂ is a C₁-C₂₀ alkyl radical, optionally comprising at least one polymerizable group, and X is OH, Cl, Br, or I.

5. The photosensitive polymer composition according to claim 1 comprising:
5.0 to 95.0 mol % of the total amount of moles of diamine units in the polymer of diamine (D), and
5.0 to 95.0 mol % of the total amount of moles of diamine units in the polymer of diamine (D1).

6. The photosensitive polymer composition according to claim 1, wherein the diamine (D1) is selected from the group consisting of 4,4′-diaminodiphenyl ether (ODA), p-phenylenediamine, (PDA), 3,3′-Diamino-5, 5′-bis (trifluoromethyl) biphenyl (TFMB), m-phenylenediamine, diphenyl dimethyl methane diamine (DMMDA), 1,3-bis (3-aminophenoxy) benzene (BAPB), 4,4′-bisphenol A ether diamine (BAPP), 4,4′-bis (4-aminophenoxy) diphenylsulfone (BAPS), 4,4′-bis (4-aminophenoxy) diphenyl ether (BAPE), diamino diphenyl (methyl) ketone (DABP), 4,4′-diamino-triphenylamine (DATPA), 4,4′-diaminodiphenyl methane (MDA), diaminodiphenyl sulfone (DDS), 3,4′-diaminodiphenyl ether (3,4′-ODA), 3,3′-dimethyl-4,4′-diamino diphenyl methane (MDI), 4,4′-diamino-diphenoxy-1″,4″-benzene, 4,4′-diamino-diphenoxy-1″,3″-benzene, 3,3′-diamino-diphenoxy-1″,3″-benzene, 4,4′-diamino-diphenyl-4″,4-phenyl-isopropyl propane, perfluorinated isopropylidene diamine (4-BDAF), 2,2-bis (4-aminophenyl) hexafluoropropane (6FDAM), 1,4-bis-(4-amino-2-trifluoromethylphenoxy) benzene (6FAPB), 2,5-bis(4-amino-2-trifluoromethyl-phenoxy)-tert benzene (DNTBHQ-2TF), 4,4′-bis (4-amino-2-trifluoromethyl-phenoxy)-biphenyl (DNBP-2TF), 5-trifluoromethyl-1,3-diaminobenzene (TFMB), 5-trifluoromethoxy-1,3-diaminobenzene (TFMOB), 1,4-diamino-2,3,5,6-tetrafluoro-benzene (4FPPD), 4,4′-diamino octafluoro biphenyl (8FZB), 4,4′-diamino diphenyl ether octafluoro (8FODB), bis (3-amino-phenyl)-4-(trifluoromethyl) phenyl phosphine oxide (m-DA6FPPO), and 2,2-Bis(4-aminophenyl)hexafluoropropane (BPAFDA).

7. The photosensitive polymer composition according to claim 1, wherein the photosensitive polymer composition comprises:
from 1 to 70 parts by weight of polyimide-based polymer,
from 1 to 30 parts by weight of a photosensitive agent, and
from 0 to 20 parts by weight of one or more additives,
with respect to a total of 100 parts by weight of the photosensitive polymer composition.

8. A pattern forming method, said method comprising:
a) applying a coating of the photosensitive polymer composition of claim 1 on a substrate;
b) masking the applied coating with a photomask having a pattern;
c) exposing the masked substrate obtained in step b) to a source of actinic radiation and developing the substrate; and
d) heat curing the developed substrate obtained in step c) to form a polyimide pattern.

9. The method of claim 8, wherein the photosensitive polymer composition further comprises (b) at least one photosensitive agent, wherein the photosensitive agent is selected from the group consisting of o-quinone diazide compounds, azide compounds, and diazo compounds.

10. The method of claim 8 wherein the photosensitive composition comprises a polyimide-based polymer obtained by polymerizing:
a component (AC) of formula (V) 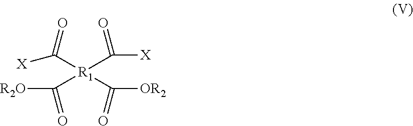
wherein R₂ is a C₁-C₂₀ alkyl radical comprising at least one polymerizable group and wherein the photosensitive agent is selected from the group consisting of acylphosphine oxides, benzophenone and its derivatives, oximes and oxime esters, and acetophenone derivatives.

11. A polyimide-based polymer obtained by polymerizing:
a component (AC) of formula (V) 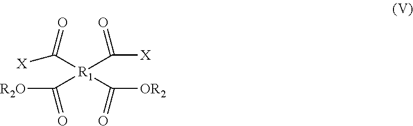
wherein R₁ is an aromatic tetravalent group, which may comprise one or more than one aromatic ring, which may be optionally fused together, R₂ is a C₁-C₂₀ alkyl radical, optionally comprising at least one polymerizable group, and X is OH, Cl, Br, or I;
a diamine component, diamine (D), wherein diamine (D) is an organic fluorinated diamine of formula (I): 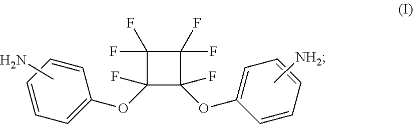
and
optionally, a diamine component, diamine (D1), different from diamine (D).

12. The polyimide-based polymer of claim 11 wherein R₂ is a C₁-C₂₀ alkyl radical comprising at least one polymerizable group.

13. A polyimide polymer obtained from the polyimide-based polymer of claim 11.

14. An article comprising at least one polyimide polymer of claim 13.

15. The photosensitive polymer composition according to claim 1, further comprising (b) at least one photosensitive agent.

16. The photosensitive polymer composition according to claim 1 wherein component (AC) is a tetracarboxylic anhydride selected from the group consisting of pyromellitic dianhydride (PMDA), 3,3′,4,4′-biphenyl tetracarboxylic dianhydride (BPDA), 4,4′-oxydiphthalic anhydride (ODPA), isomeric diphenyl sulfide dianhydride (TDPA), triphenyl diether dianhydride (HQDPA), 3,3′, 4,4′-benzophenone tetracarboxylic dianhydride (BTDA), 4,4′-bisphenol A dianhydride (BPADA), 3,3′,4,4′-diphenyl sulfone tetracarboxylic dianhydride (DSDA), 4,4′-(hexafluoroisopropylidene)diphthalic anhydride (6-FDA), 9,9-bis (trifluoromethyl)xanthene tetracarboxylic dianhydride (6FCDA), 1,4-bis(trifluoromethyl)-2,3,5,6 pyromellitic dianhydride (P6FDA), 1,4-bis(3,4-dicarboxy-trifluorophenoxy)tetrafluorobenzene dianhydride (10-FEDA), 2,2-bis[4-(3,4-dicarboxy phenoxy) phenyl] hexafluoropropane dianhydride (BFDA) or 1,4-difluoro pyromellitic dianhydride (PF2DA).

17. The photosensitive polymer composition according to claim 1 comprising:
15.0 to 85.0 mol % of the total amount of moles of diamine units in the polymer of diamine (D), and
15.0 to 85.0 mol % of the total amount of moles of diamine units in the polymer of diamine (D1).

18. The method of claim 8 wherein the photosensitive agent is selected from the group consisting of bis (2,4,6-trimethylbenzoyl)-phenylphosphineoxide ; 4,4′-bis(dimethylamino)benzophenone; 1-phenylpropanedione-2-(o-methoxycarbonyl)oxime; 1-phenyl-3-ethoxy-propanetrione-2-(o-benzoyl)oxime; 2-hydroxy-2-methylpropiophenone; and 2,2′-diethoxyacetophenone.

19. The polyimide-based polymer of claim 12 wherein R₂ is —(CH₂)ₚ—O—C(O)C(R*)═CH₂, where R* is H or a C₁-C₅ alkyl, and p is an integer from 1 to 5.
